(19) United States
(12) Patent Application Publication
(10) Pub. No.: US 2016/0010182 A1
(43) Pub. Date: Jan. 14, 2016

(54) ADVANCED BOND COAT

(71) Applicant: Rolls-Royce Corporation, Indianapolis, IN (US)

(72) Inventor: Kang N. Lee, Zionsville, IN (US)

(73) Assignee: Rolls-Royce Corporation, Indianapolis, IN (US)

(21) Appl. No.: 14/106,464

(22) Filed: Dec. 13, 2013

Related U.S. Application Data
(60) Provisional application No. 61/790,201, filed on Mar. 15, 2013.

(51) Int. Cl. C22C 19/05; C23C 16/06; B32B 15/01; C22C 19/00

(52) U.S. Cl. CPC C22C 19/056; C22C 19/057; C22C 19/007; C23C 16/06; B32B 15/01

(57) ABSTRACT

In some examples, an alloy may include less than 55 atomic percent aluminum; between about 10 and about 25 atomic percent of a platinum group metal; and a balance of nickel; at least one of chromium, silicon, tantalum, or cobalt; a reactive element; and diffusion impurities; where the alloy has a discrete gamma-prime Ni₃Al region and a discrete beta NiAl region. In some examples, a coating system may include a substrate; a first layer including gamma-prime Ni₃Al; and a second layer including beta NiAl, where the first region and the second region are discrete dual region.

This application claims the benefit of U.S. Provisional Application No. 61/790,201, filed Mar. 15, 2013, which is incorporated herein by reference in its entirety.

### TECHNICAL FIELD

The present disclosure generally relates to high temperature coatings.

### BACKGROUND

Present approaches to high temperature coatings suffer from a variety of drawbacks, limitations, disadvantages and problems including those respecting substrate compatibility and others. There is a need for the unique and inventive coating apparatuses, systems and methods disclosed herein.

### SUMMARY

In some examples, the disclosure describes an alloy including less than about 55 atomic percent aluminum, between about 10 and about 25 atomic percent of a platinum group metal, and a balance nickel; at least one of chromium, silicon, tantalum, or cobalt, a reactive element; and diffusion impurities. In accordance with these examples, the alloy comprises a discrete gamma-prime Ni₃Al region and a discrete beta NiAl region.

In some examples, the disclosure describes a coating system including a substrate, a first layer including a gamma-prime Ni₃Al composition, and a second layer including a beta NiAl composition. In accordance with these examples, the first layer and the second layer are discrete dual layers.

In some examples, the disclosure describes a method including positioning a substrate and a precursor in a sealed vessel. In accordance with these examples, the precursor comprises at least one of a solid halide or a combination of a halide activator and a donor. The method also may include vacuum purging and backfilling the sealed vessel, heating the substrate and the precursor in the sealed vessel to generate a coating gas from the precursor, and reacting the coating gas with the substrate to form a discrete dual region coating including a first region of gamma-prime Ni₃Al and a second region of beta NiAl

### BRIEF DESCRIPTION OF THE FIGURES

FIG. 1 is a conceptual cross-sectional diagram illustrating an example coating system including gamma-prime and beta phase discrete dual regions.

FIG. 2 is a cross-section of an example coating system including gamma-prime and beta phase discrete dual regions.

FIG. 3 is flow diagram illustrating an example coating technique for forming a coating system including gamma-prime and beta phase discrete dual regions.

FIG. 4a is a cross-section of an example gamma-prime and beta phase discrete dual region coating modified with platinum and a reactive element showing negligible hot corrosion attack.

FIG. 4b is a cross-section of an example beta phase coating in which about 25% of the beta coating was penetrated by hot corrosion attack.

### DETAILED DESCRIPTION

For the purposes of promoting an understanding of the principles of the disclosure, reference will now be made to the examples illustrated in the drawings and specific language will be used to describe the same. It will nevertheless be understood that no limitation of the scope of the disclosure is thereby intended. Any alterations and further modifications in the described examples, and any further applications of the principles of the disclosure as described herein are contemplated as would normally occur to one skilled in the art to which the disclosure relates.

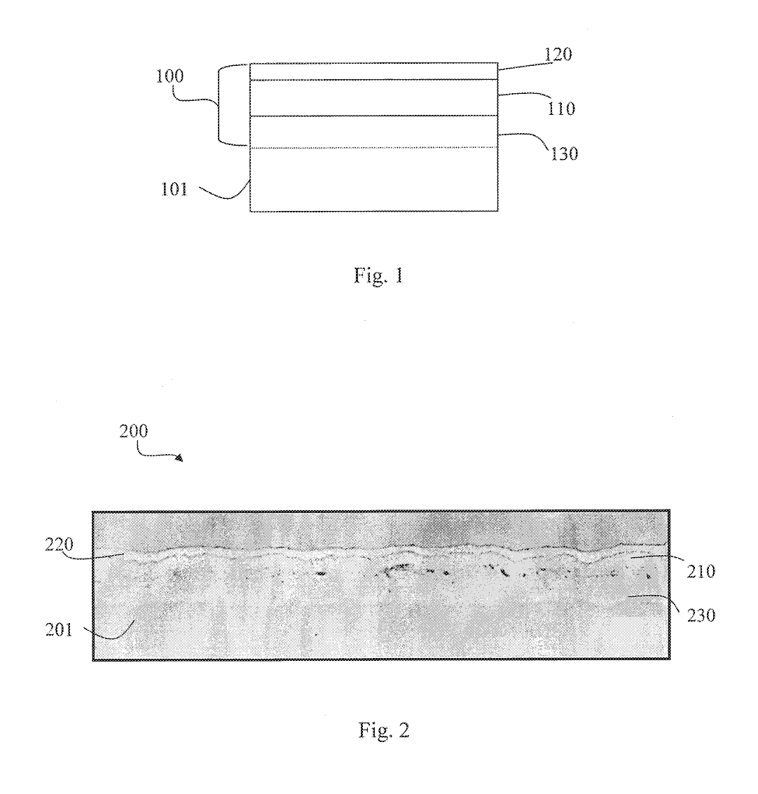

FIG. 1 is a conceptual cross-sectional diagram illustrating an example coating system 100 including gamma-prime and beta phase discrete dual regions. Coating system 100 is shown on a substrate 101. Coating system 100 includes an alloy of nickel and aluminum. The alloy of coating system 100 has gamma-prime Ni₃Al and beta NiAl phases, and the beta NiAl phase layer 120 is disposed on the gamma-prime Ni₃Al phase layer 110 creating a discrete dual region coating system. In some examples, one or both phase layers 110 and 120 can be modified by a platinum group metal and/or reactive element such as hafnium, yttrium, zirconium, chromium, and silicon. The platinum group metal and reactive element can enhance hot corrosion resistance and thermal barrier characteristics.

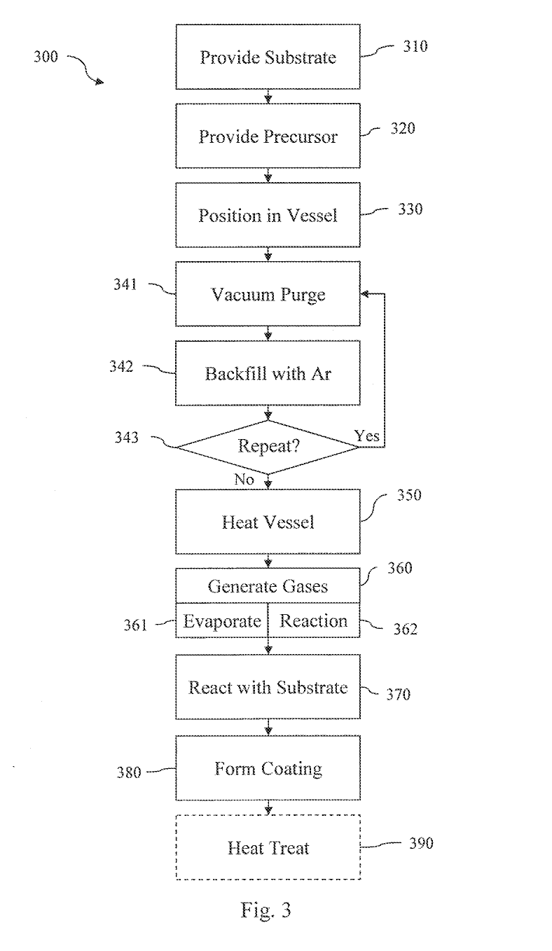

As shown in FIG. 1, in some examples, a transition zone 130 can be present when coating system 100 is deposited on substrate 101. In some examples, substrate 101 may include a high temperature superalloy. In some examples, transition zone 130 can be located between the gamma-prime Ni₃Al phase layer 110 and substrate 100. In some examples, transition zone 130 includes a gamma Ni/gamma-prime Ni₃Al region. Coating system 100 can include a barrier coating with a composition and morphology selected for mechanical compatibility with a substrate and long term oxidation resistance. FIG. 2 is a cross-section of an example coating system including gamma-prime and beta phase discrete dual regions. In the example illustrated in FIG. 2, both a gamma-prime Ni₃Al layer 210 and a beta NiAl layer 220 are modified by platinum and a reactive element. In FIG. 2, coating system 200 includes a gamma-prime Ni₃Al layer 210 and a beta NiAl layer 220. Gamma-prime Ni₃Al layer 210 and beta NiAl layer 220 are discrete dual regions on substrate 201. A transition zone 230 of gamma-Ni and gamma-prime Ni₃Al phases is present between gamma-prime Ni₃Al layer 210 and substrate 201.

In some examples, with a discrete dual region coating system, elements of the coating alloy can be non-homogeneous throughout the coating. For example, the aluminum content (e.g., atomic percent) may vary from the outer surface of coating system 100 (FIG. 1) to the region adjacent substrate 101. A gamma-prime Ni₃Al phase, the region adjacent substrate 101, has an aluminum atomic percent of less than 25 at %. A beta NiAl phase, the region at the outer surface of coating system 100, has an aluminum atomic percent of between 25 at % and about 60 at %. The aluminum atomic percent varies from less than 25 at % to greater than 25 at % through the thickness of coating system 100.

In some examples, coating system 100 may be formed using a static chemical vapor deposition process 300, such as the example technique illustrated in the flow diagram of FIG. 3. Static CVD process 300 includes providing a substrate (310). The substrate can be a high temperature superalloy (e.g., substrate 101, FIG. 1). In some examples, the substrate can also be part of a turbine blade or vane.

Static CVD process 300 also includes providing a coating precursor (320). In some examples, a coating precursor can be a solid halide or a combination of a halide activator and a donor, containing coating element(s). The technique further includes placing the substrate and the coating precursor in a sealed vessel (330). Positioning of the substrate and precursor in the sealed vessel can be adjusted for a selected coating composition, thickness and microstructure. The coating system thickness (e.g., the thickness of coating system 100) can vary with the parameters of static CVD process 300. A substrate which is internal to a component can also be coated where the coating gases are directed to the internal surface using a gas feeding fixture.

Static CVD process 300 further includes vacuum purging the vessel (341); and, backfilling the vessel with high purity argon (342). It is then determined whether the vacuum purging (341) and backfilling (342) are to be repeated (343). In some examples, the purge and backfill sequence can be repeated several times. The repetition of this sequence can minimize the oxygen content in the sealed vessel. The vessel then can be heated (350) to a temperature selected to generate coating gas(es) by various mechanisms. The temperature can be between about 1500° F. (about 815° C.) and about 1900° F. (about 1038° C.). For example, the temperature can be between about 1600° F. (about 871° C.) and about 1800° F. (about 982° C.).

A coating gas is then generated (360) by the heating (350). In some examples, generating the coating gas (360) includes evaporating a solid halide. In some examples, generating the coating gas (360) includes facilitating an activator-donor reaction (362) to generate the coating gases. The coating gases subsequently react with one or more substrate elements (370). This reaction form a coating system (e.g., coating system 100) with gamma-prime Ni₃Al/beta NiAl discrete dual regions (380). In some examples, the coating process can have a duration of up to 10 hours, such as a duration of between about 1 hour and about 3 hours. In some examples, static CVD process 300 can include an optional post-deposition heat treatment (390).

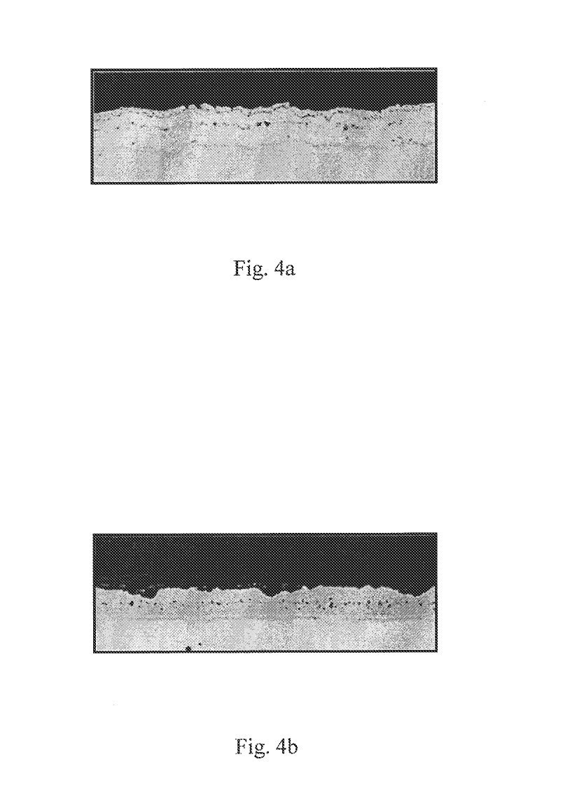

In high temperature coatings, aluminum can provide a reservoir for supplying aluminum to form a protective alumina scale, which provides oxidation resistance. A beta-NiAl phase coating has a high level of aluminum that can provide the reservoir of aluminum for long term oxidation resistance. A gamma-prime Ni₃Al phase between the beta-NiAl phase and the substrate appears to restrict the formation of microstructural instabilities at the coating/substrate interface and suppress the extent of aluminum diffusion into the substrate. FIG. 4a is a cross-section of an example gamma-prime Ni₃Al and beta NiAl phase discrete dual region coating modified with platinum and a reactive element showing negligible hot corrosion attack. FIG. 4b is a cross-section of a beta NiAl phase coating where about 25% of the beta coating was penetrated by hot corrosion attack.

An example composition of the discrete dual regions of a coating system of the present application can include the following:

Gamma-Prime Coating Composition:

Up to 25 atomic percent (at. %) (such as between about 10 at. % and about 22 at. %) aluminum

Up to 30 at. % (such as between about 10 at. % and about 20 at. %) platinum group metal

Up to 35 at. % (such as between about 10 at. % and about 30 at. %) chromium

Up to 5 at. % (such as between about 2 at. % and about 4 at. %) silicon

Up to 2 at. % (such as between about 0.01 at. % and about 1 at. %) reactive element

Diffusion Products from Substrate (Co, Ti, Mo, Re, Ta, W, Etc.)

Balance Ni

Beta Coating Composition:

Up to 55 at. % (such as between about 30 at. % and about 50 at. %) aluminum

Up to 30 at. % (such as between about 10 at. % and about 20 at. %) platinum group metal

Up to 35 at. % (such as between about 5 at. % and about 20 at. %) chromium

Up to 5 at. % (such as between about 2 at. % and about 4 at. %) silicon

Up to 2 at. % (such as between about 0.01 at. %˜1 at. %) reactive element

Diffusion Products from Substrate (Co, Ti, Mo, Re, Ta, W, Etc.)

Balance Ni

Additional elements that may be deposited for thermal barrier life and hot corrosion resistance include a platinum group metal and reactive elements such as hafnium, yttrium, zirconium, chromium, and silicon. The platinum group metal can be incorporated by electroplating the platinum on the substrate (e.g., substrate 101) and subsequently heat treating the platinum-plated substrate at a temperature sufficient to diffuse the platinum into the substrate. The aluminum and reactive elements can be deposited via the CVD steps of the coating process on the platinum diffused substrate.

Aluminum deposition can utilize a precursor of a solid AlCl₃ and/or a combination of a halide activator such as NH₄Cl, NH₄HF₂ or HCl, and an aluminum or Al—Cr alloy donor. The reactive element deposition can utilize a precursor of either a solid halide of the reactive element(s) or a combination of a halide activator and a reactive element or a reactive element-containing alloy donor. The resulting coating system may include discrete dual regions of a (Ni+Pt)₃Al gamma-prime phase and a NiPtAl beta phase modified with reactive elements. The coating system can also contain elements such as Co, Ti, Mo, Re, Ta, W, etc. which can diffuse from the substrate during the CVD step and post-CVD heat treatment step of the coating process.

In some examples, coating elements can be deposited simultaneously or co-deposited during the coating process. In other examples, coating elements can be deposited sequentially. In other examples, a portion of the coating elements can be simultaneously deposited and another portion of the coating elements can be sequentially deposited. Simultaneous or sequential deposition can be determined to provide a selected coating composition.

Some examples of coating processes can include:

### Example 1

Al+(Hf, Zr, and/or Y) chemical vapor deposition (CVD)

### Example 2

Cr CVD→Al+(Hf, Zr, and/or Y) CVD

### Example 3

Hf CVD→Al+(Hf, Zr, and/or Y) CVD

### Example 4

Cr CVD→(Hf, Zr, and/or Y) CVD→Al CVD

### Example 5

Si CVD→Al+(Hf, Zr, and/or Y) CVD

### Example 6

Si CVD→(Hf, Zr, and/or Y) CVD→Al CVD

In some examples, the disclosure describes an alloy including less than about 55 atomic percent aluminum; between about 10 and about 25 atomic percent of a platinum group metal; and a balance of the alloy being nickel, one or more of chromium, silicon, tantalum, cobalt, and a reactive element, and diffusion impurities; where the alloy has a discrete gamma-prime Ni₃Al region and a discrete beta NiAl region.

In some of these examples, the reactive element may include one or more of hafnium, yttrium, zirconium, lanthanum and cerium with an average of less than about 2 atomic percent or an average of less than 0.5 atomic percent. In some of these examples, the one or more of chromium, silicon, tantalum, and cobalt may include an average of less than about 35 atomic percent or an average of between about 5 and about 25 atomic percent. In some of these examples, an average of the atomic percent of aluminum may be non-homogenous through the alloy or a coating system. In some of these examples, the discrete gamma-prime Ni₃Al region and the discrete beta NiAl region of the alloy may include a coating system formed on a substrate. In some of these examples, the coating system may further include a transition zone between the substrate and the discrete gamma-prime Ni₃Al region, and the transition zone may further include a gamma-Ni phase and a gamma-prime Ni₃Al phase.

In some examples, the disclosure describes a coating system including a substrate; a first layer including a gamma-prime Ni₃Al composition; and a second layer including a beta NiAl composition; wherein the first layer and the second layer are discrete dual layers. In some of these examples, the gamma-prime Ni₃Al composition includes less than about 25 atomic percent aluminum, between about 10 and about 25 atomic percent of a platinum group metal, and a balance of the gamma-prime Ni₃Al composition may include nickel, one or more of chromium, silicon, tantalum, cobalt, and a reactive element, and diffusion impurities. In some of these examples the beta NiAl composition may include between about 25 and about 55 atomic percent aluminum, between about 10 and about 25 atomic percent of a platinum group metal, and the balance of the beta NiAl composition may include nickel, one or more of chromium, silicon, tantalum, cobalt, and a reactive element, and diffusion impurities.

In some of these examples, the first layer may include a platinum group metal modified gamma-prime Ni₃Al alloy and the second layer may include a platinum group metal modified beta NiAl alloy. In some of these examples, the first layer may include a reactive element modified gamma-prime Ni₃Al alloy and the second layer may include a reactive element modified beta NiAl alloy. In some of these examples, the substrate may include a high temperature superalloy. In some of these examples, the coating system may include a hot corrosion resistant coating and a thermal barrier coating. In some of these examples, a transition zone may be between the substrate and the first layer, and the transition zone can further include a gamma-Ni phase and a gamma-prime Ni₃Al phase.

In some examples, the disclosure describes a method including providing a substrate; providing a precursor; positioning the substrate and the precursor in a sealed vessel; vacuum purging and backfilling the sealed vessel; heating the substrate and the precursor in the sealed vessel; generating a coating gas from the precursor; reacting the coating gas with the substrate; and forming a discrete dual region coating including a first region of gamma-prime Ni₃Al and a second region of beta NiAl.

In some of these examples, forming the discrete dual region coating may include forming the first region of gamma-prime Ni₃Al including less than about 25 atomic percent aluminum; between about 10 and about 25 atomic percent of a platinum group metal; and a balance of the gamma-prime Ni₃Al being nickel, one or more of chromium, silicon, tantalum, cobalt, and a reactive element, and trace impurities. In some of these examples, forming the discrete dual region coating may include forming the second region of beta NiAl including between about 25 and about 55 atomic percent aluminum; between about 10 and about 25 atomic percent of a platinum group metal; and the balance of the beta NiAl being nickel, one or more of chromium, silicon, tantalum, cobalt, and a reactive element, and diffusion impurities.

In some of these examples, the substrate may include a high temperature superalloy. In some of these examples, the precursor may include a solid halide or a combination of a halide activator and a donor. In some of these examples, the method may further include electroplating a platinum group metal on the substrate, and forming the discrete dual region coating further includes forming a platinum group metal modified gamma-prime Ni₃Al and beta NiAl discrete dual region coating system. In some examples, the method may further include post-deposition heat treating the discrete dual region coating. In some of these examples, the method may include repeating the vacuum purging and backfilling. In some examples, the method may include depositing one or more elements of the discrete dual region coating in an order selected from a group consisting of simultaneous, co-deposited, sequential and combinations thereof.

While the disclosure has been illustrated and described in detail in the drawings and foregoing description, the same is to be considered as illustrative and not restrictive in character, it being understood that only the some examples have been shown and described and that all changes and modifications that come within the spirit of the disclosure are desired to be protected. It should be understood that while the use of words such as preferable, preferably, preferred or more preferred utilized in the description above indicate that the feature so described may be more desirable, it nonetheless may not be necessary and examples lacking the same may be contemplated as within the scope of the disclosure, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. An alloy comprising:
less than about 55 atomic percent aluminum;
between about 10 and about 25 atomic percent of a platinum group metal; and
a balance nickel; at least one of chromium, silicon, tantalum, or cobalt, a reactive element; and diffusion impurities; wherein the alloy comprises a discrete gamma-prime Ni₃Al region and a discrete beta NiAl region.

2. The alloy of claim 1, wherein the reactive element includes at least one of hafnium, yttrium, zirconium, lanthanum, or cerium.

3. The alloy of claim 2, wherein the alloy comprises an average reactive element content of less than about 2 atomic percent.

4. The alloy of claim 2, wherein the alloy comprises an average reactive element content of less than about 0.5 atomic percent.

5. The alloy of claim 1, wherein the alloy comprises an average content of the at least one of chromium, silicon, tantalum, or cobalt of less than about 35 atomic percent.

6. The alloy of claim 1, wherein the alloy comprises an average content of the at least one of chromium, silicon, tantalum, or cobalt of between about 5 and about 20 atomic percent.

7. The alloy of claim 1, wherein the discrete gamma-prime Ni₃Al region and the discrete beta NiAl region of the alloy include a coating system on a substrate.

8. The alloy of claim 7, wherein the coating system further includes a transition zone between the substrate and the discrete gamma-prime Ni₃Al region, and wherein the transition zone includes a gamma-Ni phase and a gamma-prime Ni₃Al phase.

9. The alloy of claim 7, wherein an average of the atomic percent of aluminum is non-homogenous through the coating system.

10. A coating system comprising:
a substrate;
a first layer including a gamma-prime Ni₃Al composition; and
a second layer including a beta NiAl composition, wherein the first layer and the second layer are discrete dual layers.

11. The coating system of claim 10, wherein the gamma-prime Ni₃Al composition includes:
less than about 25 atomic percent aluminum;
between about 10 and about 25 atomic percent of a platinum group metal; and
a balance of nickel; at least one of chromium, silicon, tantalum, of cobalt; a reactive element; and diffusion impurities.

12. The coating system of claim 10, wherein the beta NiAl composition includes:
between about 25 and about 55 atomic percent aluminum;
between about 10 and about 25 atomic percent of a platinum group metal; and
a balance of nickel; at least one of chromium, silicon, tantalum, or cobalt; a reactive element; and diffusion impurities.

13. The coating system of claim 10, wherein the first layer includes a platinum group metal modified gamma-prime Ni₃Al alloy and the second layer includes a platinum group metal modified beta NiAl alloy.

14. The coating system of claim 10, wherein the first layer includes a reactive element modified gamma-prime Ni₃Al alloy and the second layer includes a reactive element modified beta NiAl alloy.

15. The coating system of 10, further including a transition zone between the substrate and the first layer, wherein the transition zone includes a gamma-Ni phase and a gamma-prime Ni₃Al phase.

16. A method comprising:
positioning a substrate and a precursor in a sealed vessel, wherein the precursor comprises at least one of a solid halide or a combination of a halide activator and a donor;
vacuum purging and backfilling the sealed vessel;
heating the substrate and the precursor in the sealed vessel to generate a coating gas from the precursor; and
reacting the coating gas with the substrate to form a discrete dual region coating including a first region of gamma-prime Ni₃Al and a second region of beta NiAl.

17. The method of claim 16, wherein the first region of gamma-prime Ni₃Al includes:
less than about 25 atomic percent aluminum;
between about 10 and about 25 atomic percent of a platinum group metal; and
a balance of nickel; at least one of chromium, silicon, tantalum, or cobalt; a reactive element; and diffusion impurities.

18. The method of claim 16, wherein the second layer of beta NiAl includes:
between about 25 and about 55 atomic percent aluminum;
between about 10 and about 25 atomic percent of a platinum group metal; and
a balance of nickel; at least one of chromium, silicon, tantalum, or cobalt; a reactive element; and diffusion impurities.

19. The method of claim 16, further comprising electroplating a platinum group metal on the substrate, and wherein forming the discrete dual region coating comprises forming a platinum group metal modified gamma-prime Ni₃Al and beta NiAl discrete dual region coating system.

20. The method of claim 16, further comprising depositing one or more elements of the discrete dual region coating in an order selected from a group consisting of simultaneous, co-deposited, sequential and combinations thereof.
